(19) United States
(12) Patent Application Publication
(10) Pub. No.: US 2024/0304411 A1
(43) Pub. Date: Sep. 12, 2024

(54) SEMICONDUCTOR STRUCTURE, INSPECTION METHOD AND INSPECTION SYSTEM

(71) Applicant: Winbond Electronics Corp., Taichung City (TW)

(72) Inventor: Yen-Chiao CHEN, Taichung City (TW)

(73) Assignee: Winbond Electronics Corp., Taichung City (TW)

(21) Appl. No.: 18/178,944

(22) Filed: Mar. 6, 2023

(51) Int. Cl. H01J 37/26; G06T 7/00; H01J 37/22; H01J 37/28

(52) U.S. Cl. CPC H01J 37/265; G06T 7/0004; H01J 37/222; H01J 37/28; G06T 2207/10061; G06T 2207/30148; H01J 2237/2817

(57) ABSTRACT

An inspection method for inspecting a semiconductor structure is provided. The semiconductor structure includes a first conductive line, a second conductive line, a first conductive line contact and first transistors connected to the first conductive line, and second transistors connected to the second conductive line, wherein each of the first transistors includes a first contact and each of the second transistors includes a second contact. The inspection method includes a pre-charge operation, irradiating the first conductive line contact with an electron beam; an imaging operation, obtaining an image of the semiconductor structure; and a determination operation, which determines whether the second contact of any one of the second transistors becomes bright in the image. In response to the second contact of the any one of the second transistors becoming bright, the determination operation determines that there is a defect between the first conductive line and the second conductive line.

### BACKGROUND OF THE INVENTION

### Field of the Invention

The present disclosure relates to an inspection method, and, in particular, to an inspection method that utilizes the bright and dark states of source/drain contacts in a scanning electron microscope (SEM) image to determine the presence of defects between conductive lines.

### Description of the Related Art

E-beam inspection (EBI) is often used for in-line inspection for defects in semiconductor structures. EBI utilizes SEM images to search for defects in semiconductor devices in the manner of image processing.

However, since the scaling down of semiconductor devices and components has been accompanied by a concomitant reduction in the size of the defects, it has become increasingly difficult to find such defects in SEM images. For example, when the size of the defect is only a few pixels wide in a SEM image, it is very difficult to pinpoint this defect in the SEM image due to the limitations of resolution.

### BRIEF SUMMARY OF THE INVENTION

An embodiment of the present disclosure provides an inspection method for inspecting a semiconductor structure. The semiconductor structure comprises a first conductive line and a second conductive line extending in a first direction and spaced apart from each other in a second direction; first transistors connected to the first conductive line and second transistors connected to the second conductive line, wherein each of the first transistors includes a first contact and each of the second transistors includes a second contact; and a first conductive line contact connected to the first conductive line. The inspection method comprises a pre-charge operation, irradiating the first conductive line contact with an electron beam; an imaging operation, obtaining an image of the semiconductor structure; and a determination operation, determining whether the second contact of any one of the second transistors becomes bright in the image. In response to the second contact of the any one of the second transistors becoming bright, the determination operation determines that there is a defect between the first conductive line and the second conductive line.

An embodiment of the present disclosure provides a semiconductor structure which comprises a first conductive line and a second conductive line extending in a first direction and spaced apart from each other in a second direction; first transistors connected to the first conductive line and second transistors connected to the second conductive line, wherein each of the first transistors includes a first contact and each of the second transistors includes a second contact; and a first conductive line contact connected to the first conductive line.

In addition, an embodiment of the present disclosure provides an inspection system for inspecting the semiconductor structure. The inspection system comprises an electron beam emitting system having an electron source and a detector, a stage configured to carry the semiconductor structure, and a processing device. The processing device is configured to perform a pre-charge operation, an imaging operation, and a determination operation. The pre-charge operation emits an electron beam toward the first conductive line contact of the semiconductor structure through the electron source. The imaging operation scans the semiconductor structure and receiving secondary electrons that come from the semiconductor structure through the detector to generate an image of the semiconductor structure. The determination operation discerns a bright state and a dark state in the image, to determine whether there is a defect between the first conductive line and the second conductive line of the semiconductor structure.

### BRIEF DESCRIPTION OF THE DRAWINGS

FIG. 1A illustrates a top view of a semiconductor structure, in accordance with some embodiments of the present disclosure;

FIG. 1B illustrates a cross-section view of the semiconductor structure taken along a line A-A of FIG. 1A, in accordance with some embodiments of the present disclosure;

FIG. 2A illustrates a schematic diagram of the bright and dark states of the contacts of the semiconductor structure in the SEM image under a normal state, in accordance with some embodiments of the present disclosure;

FIG. 2B illustrates a schematic diagram of the bright and dark states of the contacts of the semiconductor structure in the SEM image under an abnormal state, in accordance with some embodiments of the present disclosure;

FIG. 3A illustrates a top view of a semiconductor structure, in accordance with some embodiments of the present disclosure;

FIG. 3B illustrates a cross-section view of the semiconductor structure taken along a line B-B of FIG. 3A, in accordance with some embodiments of the present disclosure;

FIG. 4A illustrates a schematic diagram of the bright and dark states of the contacts of the semiconductor structure in the SEM image under a normal state, in accordance with some embodiments of the present disclosure;

FIG. 4B illustrates a schematic diagram of the bright and dark states of the contacts of the semiconductor structure in the SEM image under an abnormal state, in accordance with some embodiments of the present disclosure;

FIG. 5 illustrates a block diagram of an inspection system, in accordance with some embodiments of the present disclosure; and

FIG. 6 illustrates a flow chart of a method for inspecting a semiconductor structure, in accordance with some embodiments of the present disclosure.

### DETAILED DESCRIPTION OF THE INVENTION

Since the defects accompanied with the scaling down of semiconductor device are very tiny, it also becomes more difficult to find defects directly from SEM images using EBI methods. In view of this, the present disclosure provides an indirect detection method that utilizes voltage contrast (VC), so as to more easily and clearly find defects from SEM images under the EBI method.

The method provided by the present disclosure includes disposing a plurality of conductive lines (e.g., word lines) parallel to each other. Each of the conductive lines is connected to gates of corresponding transistors, respectively. Or, the conductive lines act as gates of transistors. Then, non-adjacent conductive lines among the plurality of conductive lines are pre-charged to turn on the transistors connected to the conductive lines that are pre-charged. As a result, in the SEM image, the contacts disposed on source/drain regions of these transistors will occur a bright voltage contrast due to having more electrons. That is, these contacts become “bright” in the SEM image. On the other hand, since the transistors connected to the conductive lines that are not pre-charged are still in turn off state, theoretically, the contacts of these transistors should keep in “dark” state in the SEM image.

However, if there are defects (e.g., seams in the isolation structure) between the conductive lines, and conductive materials fill into the defects and make the conductive lines connect together (e.g., a short-circuit), the conductive lines that are not pre-charged will be connected to and obtain voltage from the conductive lines that have been pre-charged. As a result, the transistors connected to the conductive lines that are not pre-charged will be turned on, and the contacts of these transistors will also become bright in the SEM image. Therefore, by observing whether the contacts that should keep in the “dark” state become “bright” or not, it can determine whether there is a defect (e.g., a short-circuit) between the conductive lines. Moreover, since the size of the contact of source/drain is much greater than the size of the defect, the existence of the defect can be found more easily and clearly from the SEM image.

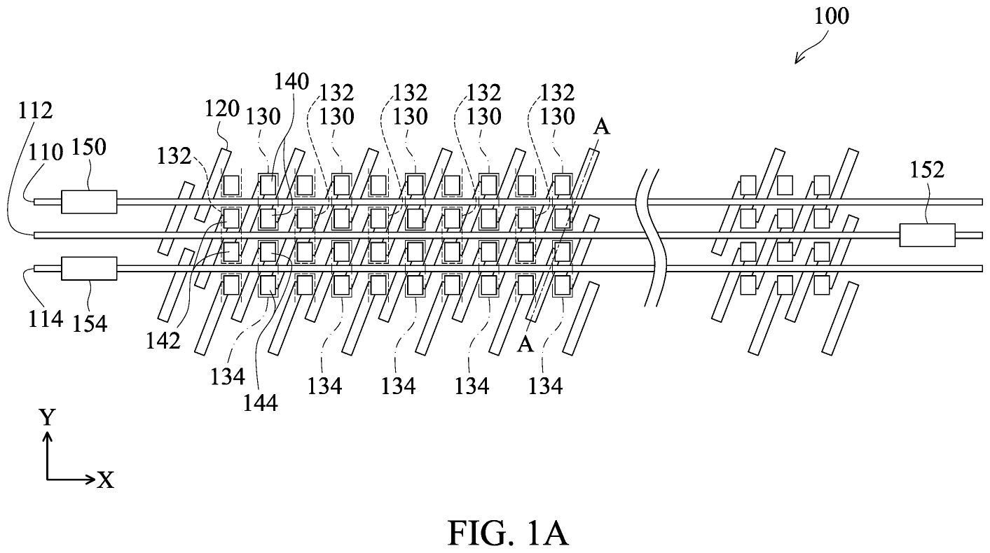

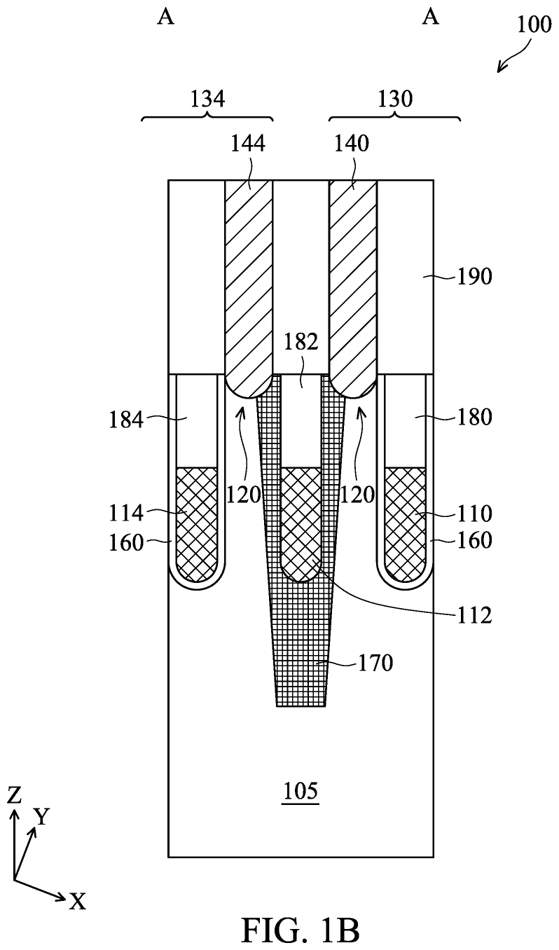

Refer to FIG. 1A, a semiconductor structure 100 includes a first conductive line 110, a second conductive line 112, and a third conductive line 114, they extend in a first direction X and are spaced apart from each other in a second direction Y. The semiconductor structure 100 further includes first transistors 130, second transistors 132, and third transistors 134. The first transistors 130 have first contacts 140 disposed on source/drain regions, the second transistors 132 have second contacts 142 disposed on the source/drain regions, and the third transistors 134 have third contacts 144 disposed on the source/drain regions. The first transistors 130 are disposed along the first conductive line 110 (i.e., in the first direction X), and two first contacts 140 of each of the first transistors 130 are disposed on opposite sides of the first conductive line 110 in the second direction Y. The second transistors 132 are disposed along the second conductive line 112, and two second contacts 142 of each of the second transistors 132 are disposed on opposite sides of the second conductive line 112 in the second direction Y. The third transistors 134 are disposed along the third conductive line 114, and two third contacts 144 of each of the third transistors 134 are disposed on opposite sides of the third conductive line 114 in the second direction Y.

In some embodiments, the first conductive line 110, the second conductive line 112, and the third conductive line 114 are word lines, and act as the gates of the first transistors 130, the second transistors 132, and the third transistors 134, respectively. In other embodiments, the first conductive line 110, the second conductive line 112, and the third conductive line 114 are connected to the gates of the first transistors 130, the second transistors 132, and the third transistors 134, respectively. In the depicted embodiment, the first transistors 130/third transistors 134 and the second transistors 132 are disposed alternately along the first direction X. As shown in FIG. 1A, the first one of the second transistors 132 is disposed in the first column, the first one of the first transistors 130 and the first one of the third transistors 134 are disposed in the second column, the second one of the second transistors 132 is disposed in the third column, and the second one of the first transistors 130 and the second one of the third transistors 134 are disposed in the fourth column, and so on.

The semiconductor structure 100 also includes a first conductive line contact 150, a second conductive line contact 152, and a third conductive line contact 154 disposed on the first conductive line 110, the second conductive line 112, and the third conductive line 114, respectively. The first conductive line contact 150, the second conductive line contact 152, and the third conductive line contact 154 may be connected to and used to pre-charge the first conductive line 110, the second conductive line 112, and the third conductive line 114, respectively. In some embodiments, the first conductive line contact 150, the second conductive line contact 152, and the third conductive line contact 154 are alternately disposed on the opposite sides of the semiconductor structure 100 in the first direction X. For example, the first conductive line contact 150 and the third conductive line contact 154 are disposed on a side of the semiconductor structure 100, and the second conductive line contact 152 is disposed on another side of the semiconductor structure 100. In alternative embodiments, the semiconductor structure 100 may only include the conductive line contacts disposed on one side. For example, the semiconductor structure 100 may only include the first conductive line contact 150 and the third conductive line contact 154, and not include the second conductive line contact 152.

For the purpose of simplicity, FIG. 1A only illustrates three conductive lines as well as corresponding conductive line contacts, corresponding transistors, and corresponding contacts disposed on source/drain regions. In practice, however, the semiconductor structure 100 may have any number of conductive lines, and each of conductive lines may be connected to any number of corresponding transistors and contacts.

Refer to FIG. 1B, the semiconductor structure 100 includes a substrate 105 and an interlayer dielectric (ILD) layer 190 over the substrate 105. The first conductive line 110, the second conductive line 112, and the third conductive line 114 are disposed in the substrate 105. A first isolation structure 180, a second isolation structure 182, and a third isolation structure 184 are disposed in the substrate 105, and disposed over the conductive line 110, the second conductive line 112, and the third conductive line 114, respectively.

The first contacts 140 (FIG. 1B only shows one first contact 140) are disposed over the source/drain regions 120 of the substrate 105, in the ILD layer 190, and on the opposite sides of the first conductive line 110. The third contacts 144 (FIG. 1B only shows one third contact 144) are disposed over the source/drain regions 120 of the substrate 105, in the ILD layer 190, and on the opposite sides of the third conductive line 114. In the cross-section view shown in FIG. 1B, since the line A-A crosses the first transistor 130 and the third transistor 134, the second contact 142 is not shown in FIG. 1B. However, in the regions of the second transistors 132, similar to the first contacts 140 and the third contacts 144, the second contacts 142 are disposed over the source/drain regions 120 of the substrate 105, in the ILD layer 190, and on the opposite sides of the second conductive line 112.

Since the line A-A crosses the first transistor 130 and the third transistor 134, in FIG. 1B, the semiconductor structure 100 includes gate dielectric layers 160 disposed around the first conductive line 110, the first isolation structure 180, the third conductive line 114, and the third isolation structure 184. The semiconductor structure 100 further includes an isolation structure 170 disposed around the second conductive line 112 and the second isolation structure 182. In the regions of the second transistors 132, the semiconductor structure 100 includes the gate dielectric layers 160 disposed around the second conductive line 112 and the second isolation structure 182, as well as the isolation structure 170 disposed around the first conductive line 110, the first isolation structure 180, the third conductive line 114, and the third isolation structure 184. In the embodiment where the first conductive line 110, the second conductive line 112, and the third conductive line 114 do not act as gates of transistors, the first transistors 130, the second transistors 132, and the third transistors 134 have additional gate structures. The gate dielectric layers are disposed around these additional gate structures. The first conductive line 110, the second conductive line 112, and the third conductive line 114 are connected to these additional gate structures through additional elements (e.g., gate contacts and/or gate vias).

In some embodiments, the first conductive line 110, the second conductive line 112, and the third conductive line 114 may include materials such as polysilicon, tungsten (W), copper (Cu), aluminum (Al), cobalt (Co), ruthenium (Ru), molybdenum (Mo), tantalum (Ta), titanium (Ti), alloys thereof, and/or combinations thereof. In some embodiments, the first contacts 140, the second contacts 142, and the third contacts 144 may include materials such as W, Cu, Al, Co, Ru, Mo, Ta, Ti, alloys thereof, and/or combinations thereof.

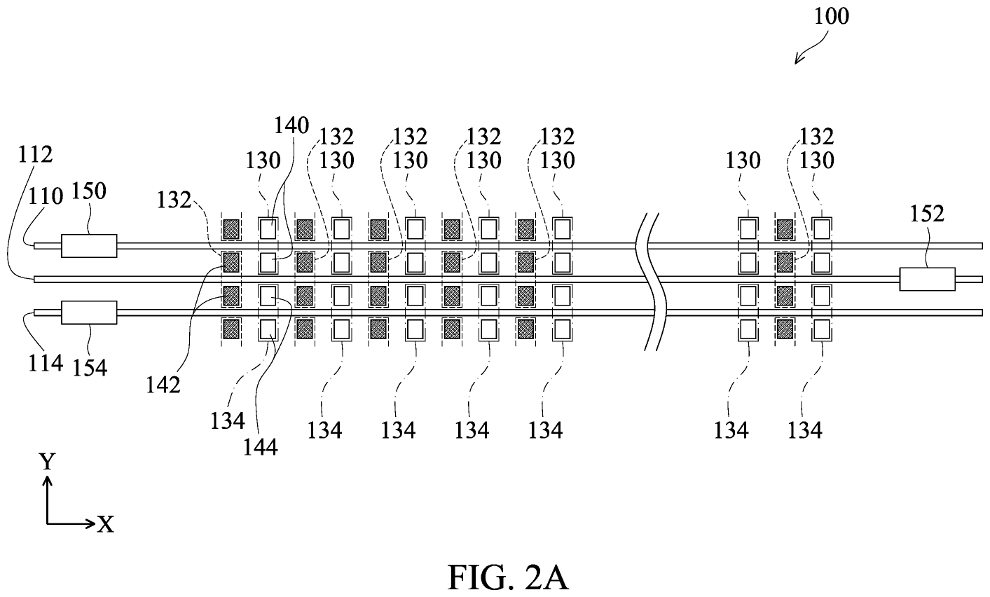

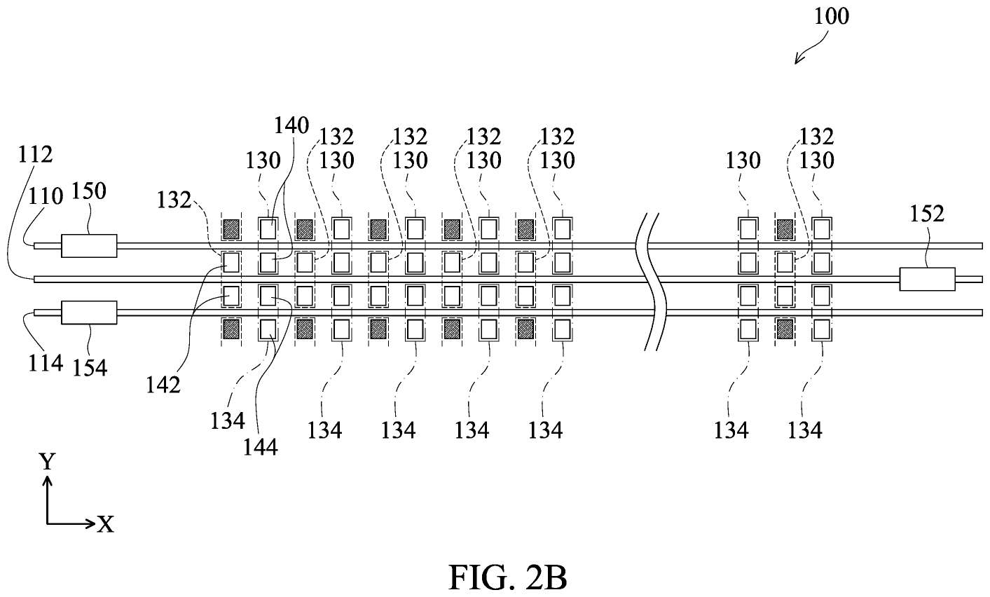

According to some embodiments of the present disclosure, FIGS. 2A and 2B illustrate the bright state (e.g., bright voltage contrast) and the dark state of the contacts of the semiconductor structure 100 in the SEM image in the normal state and the abnormal state, respectively.

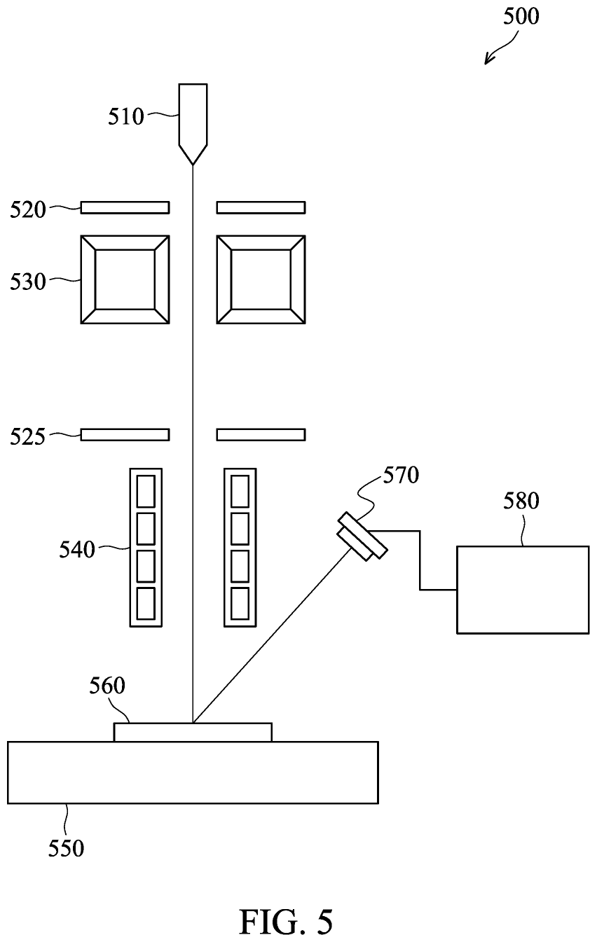

According to the inspection method provided by the present disclosure, firstly, use a first electron beam to irradiate the conductive line contacts for pre-charging. The inspection method is performed with an inspection system 500 as shown in FIG. 5. In some embodiments, the first electron beam irradiates the first conductive line contact 150 and the third conductive line contact 154 to pre-charge the first conductive line 110 and the third conductive line 114. Therefore, the first transistors 130 and the third transistors 134 connected to the first conductive line 110 and the third conductive line 114 are turned on.

Next, use a second electron beam to scan the semiconductor structure 100 and use a detector to receive the secondary electrons coming from the semiconductor structure 100 to generate a SEM image of the semiconductor structure 100. Then, use a processing device to perform image processing on the SEM image to determine whether there is a defect (e.g., a short-circuit) between the first conductive line 110, the second conductive line 112, and the third conductive line 114 of the semiconductor structure 100.

As shown in FIG. 2A, since the first transistors 130 and the third transistors 134 are turned on, the first contacts 140 of the first transistors 130 and the third contacts 144 of the third transistors 134 have more electrons, and thus the bright voltage contrast is produced. Therefore, in the SEM image, the first contacts 140 and the third contacts 144 are in the “bright” state. On the other hand, in the normal state, since the second conductive line contact 152 is not irradiated by the first electron beam and the second transistors 132 are not turned on, the second contacts 142 do not obtain additional electrons. Therefore, the second contacts 142 keep in “dark” state.

However, in the abnormal state, such as when there has been a short-circuit between the first conductive line 110, the second conductive line 112, and the third conductive line 114, the bright and dark states of the contacts of the semiconductor structure 100 in the SEM image will be different from the schematic diagram shown in FIG. 2A. Refer to FIG. 2B, since the first transistors 130 and the third transistors 134 are turned on, the first contacts 140 and the third contacts 144 are also in the “bright” state, which is the same as that in FIG. 2A.

On the other hand, although the second conductive line contact 152 is not irradiated by the first electron beam and thus the second conductive line 112 is not pre-charged, since there was a short-circuit between the second conductive line 112 and the first conductive line 110 and/or the third conductive line 114, the second conductive line 112 obtains the voltage from the first conductive line 110 and/or the third conductive line 114.

As a result, the second transistors 132 connected to the second conductive line 112 are turned on. Therefore, in the SEM image, the second contacts 142 of the second transistors 132 no longer keep in the “dark” state, but are in the “bright” state due to having more electrons. Since the second contacts 142 will become bright due to the defect (e.g., short-circuit) between the second conductive line 112 and other conductive lines, it can be determined that there is the defect between the second conductive line 112 and other conductive lines according to the second contacts 142 that become bright in the SEM image.

As described above, in the SEM image, the defect (e.g., a short-circuit) between the conductive lines will cause the contacts that should appear the “dark” state to instead appear the “bright” state. Therefore, by performing image processing on the SEM image, it can be determined whether the defect exists between the conductive lines according to the “bright” and “dark” states of the contacts. In this way, the contacts can be utilized to determine whether the defect exists in the semiconductor structure, wherein the contacts are much greater than the defect and thus are easier to observe. Furthermore, since the conductive lines are determined indirectly through the contacts, when the inspection method provided by the present disclosure is performed, the top of the conductive lines can be covered by other components. For example, as shown in FIG. 1B, when the inspection method is performed, the top of the first conductive line 110, the second conductive line 112, and the third conductive line 114 have been covered by the first isolation structure 180, the second isolation structure 182, and the third isolation structure 184. It means that the present inspection method does not need to be performed immediately while the conductive lines are formed and are exposed on the surface of the semiconductor structure. Instead, the present inspection method can be performed after a relatively complete process procedure is completed. In this way, the time and cost of redesigning the process, interrupting the process, and/or frequently entering and exiting the process chamber can be avoided. Moreover, since the present inspection method utilizes the elements of the actual semiconductor device, there is no need to particularly design a test structure for the inspection method. As a result, the semiconductor structure being a test key will have a very similar structure to a real chip being a product. It will make the inspection result of the test key be highly consistent with the real chip, thereby improving the accuracy of the inspection method.

In alternative embodiments, the first electron beam irradiates the second conductive line contact 152 instead of the first conductive line contact 150 and the third conductive line contact 154. Accordingly, the second transistors 132 connected to the second conductive line 112 are turned on, while the first transistors 130 and the third transistors 134 are not turned on. Therefore, in the normal state, in the SEM image, the second contacts 142 are in the “bright” state, while the first contacts 140 and the third contacts 144 keep in the “dark” state. On the other hand, in the abnormal state, in the SEM image, the first contacts 140 and/or the third contacts 144 become bright due to the defect (e.g., short-circuit) between the first conductive line 110, the second conductive line 112, and the third conductive line 114. As a result, it can also determine whether there is a defect between the conductive lines according to the change of “bright” and “dark” states of the contacts (e.g., the first contacts 140 and/or the third contacts 144).

In some embodiments, the conductive lines that are not pre-charged (e.g., the second conductive line 112) may be further divided into a plurality of sub-conductive lines. The plurality of sub-conductive lines may be used to further determine the region where the defect existing.

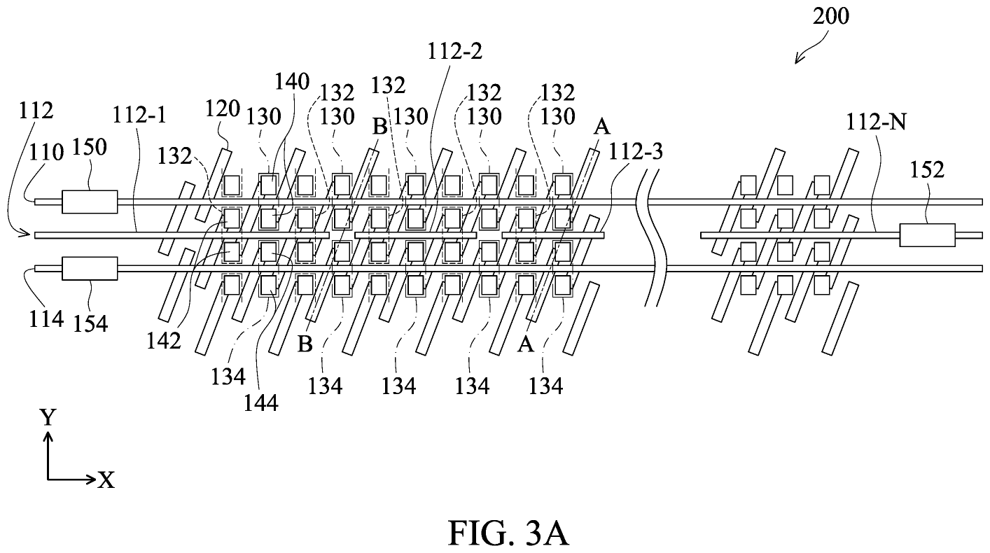

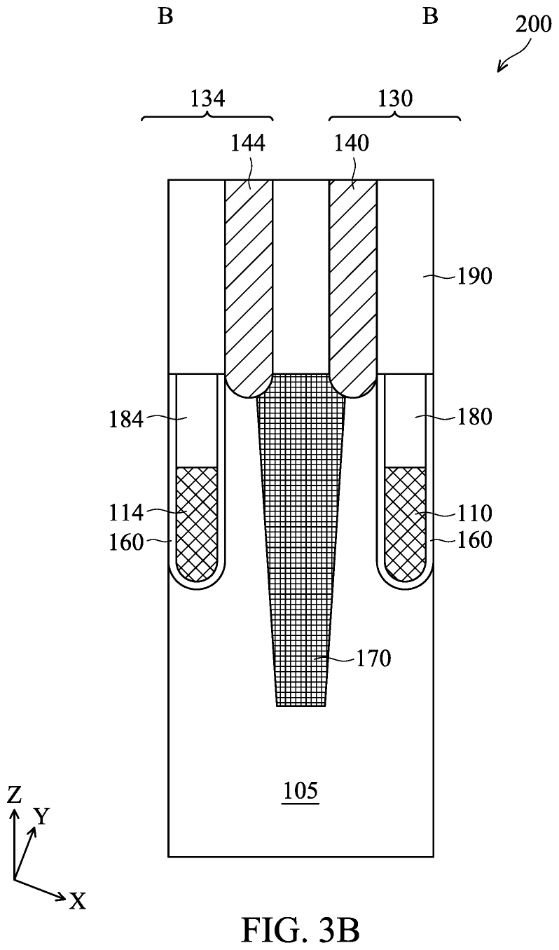

Refer to FIG. 3A, the second conductive line 112 is divided into sub-conductive lines 112-1, 112-2, 112-3, . . . , 112-N, wherein N is any positive integer. In some embodiments, the locations where the second conductive line 112 is cut are located at the transistors that are in the “bright” state under both normal and abnormal states. For example, in the embodiments where the first conductive line 110 and the third conductive line 114 are pre-charged, the locations where the second conductive line 112 is cut are located at the first transistors 130 and the third transistors 134. The locations of opposite ends of each sub-conductive line are located at the transistors that are in the “dark” state in the normal state, such as at the second transistors 132. In other words, each sub-conductive line crosses over M groups of transistors that are in the “dark” state in the normal state (e.g., the second transistors 132), wherein M is any positive integer and depends on design requirements. Each sub-conductive line crosses over M-1 groups of transistors that are in the “bright” state under both normal and abnormal states (e.g., the first transistors 130 and the third transistors 134, one first transistor 130 and one third transistor 134 are a group). In FIG. 3A, M is shown as 2 for the purpose of simplicity, however, the present disclosure is not limited thereto.

FIG. 3B is a cross-section view of the semiconductor structure 200 taken along a line B-B of FIG. 3A. The cross-section view taken along the line A-A of FIG. 3A is the same as the cross-section view in FIG. 1B, so it is not repeated herein. In FIG. 3B, the semiconductor structure 200 has a structure similar to that of the semiconductor structure 100 in FIG. 1B, the difference between FIG. 3B and FIG. 1B is that only the isolation structure 170 remains because the second conductive line 112 has been cut.

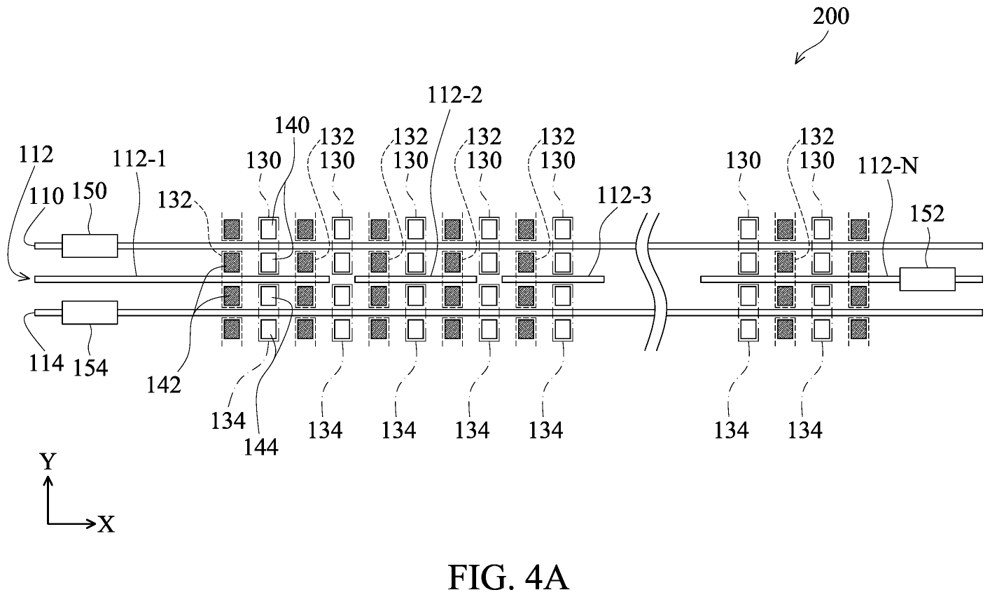

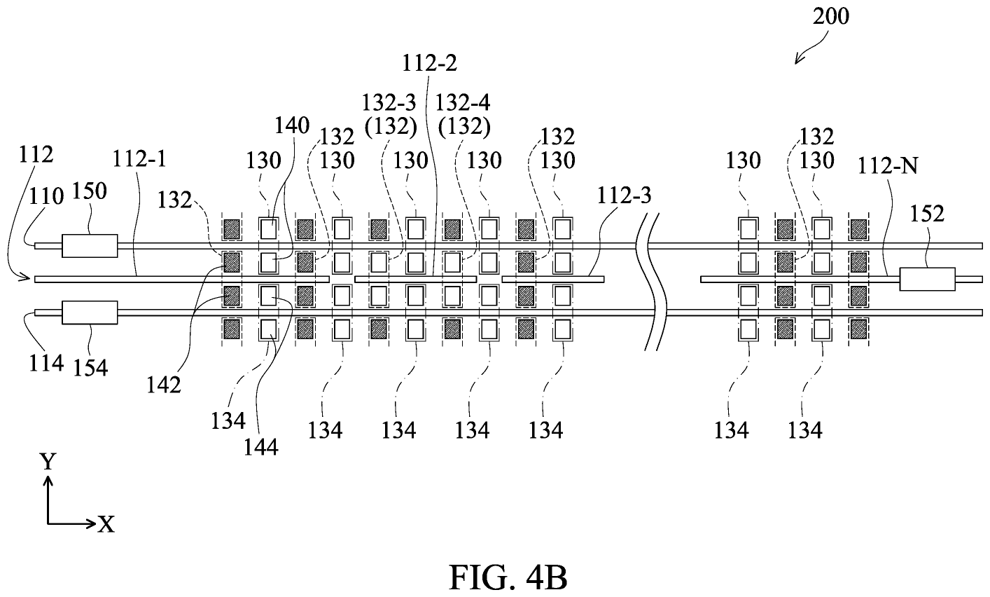

FIGS. 4A and 4B illustrate the bright state (e.g., bright voltage contrast) and the dark state of the contacts of the semiconductor structure 200 in the SEM image in the normal state and the abnormal state, respectively. For the purpose of simplicity and clarity,

FIGS. 4A and 4B omit some features in FIG. 3A.

According to the inspection method provided by the present disclosure, firstly, use the first electron beam to irradiate the conductive line contacts for pre-charging. In some embodiments, the inspection method is performed with the inspection system 500 as shown in FIG. 5. In some embodiments, the first electron beam irradiates the first conductive line contact 150 and the third conductive line contact 154 to pre-charge the first conductive line 110 and the third conductive line 114. Therefore, the first transistors 130 and the third transistors 134 connected to the first conductive line 110 and the third conductive line 114 are turned on. Next, use the second electron beam to scan the semiconductor structure 200 and use the detector to receive the secondary electrons coming from the semiconductor structure 200 to generate a SEM image of the semiconductor structure 200. Then, use a processing device to perform image processing on the SEM image to determine whether there is a defect (e.g., short-circuit) between the first conductive line 110, the second conductive line 112, and the third conductive line 114 of the semiconductor structure 200.

As described above with reference to FIG. 2A, since the first transistors 130 and the third transistors 134 are turned on, the first contacts 140 of the first transistors 130 and the third contacts 144 of the third transistor 134 are in the “bright” state in the SEM image, as shown in FIG. 4A. On the other hand, in the normal state, since the second conductive line contact 152 is not irradiated by the first electron beam and the second transistors 132 are not turned on, the second contacts 142 keep in “dark” state.

Refer to FIG. 4B, in the abnormal state, such when there has been a short-circuit between the first conductive line 110, the second conductive line 112, and the third conductive line 114, since the first transistors 130 and the third transistors 134 are turned on, the first contacts 140 and the third contacts 144 are also in the “bright” state, which is the same as that in FIG. 4A.

On the other hand, the second conductive line contact 152 is not irradiated by the first electron beam and/or the second conductive line 112 is divided in to a plurality of sub-conductive lines and thus cannot obtain voltage from the conductive line contact. However, there was a short-circuit between one or more of the sub-conductive lines 112-1˜112-N of the second conductive line 112 and the first conductive line 110 and/or the third conductive line 114. Accordingly, one or more of the sub-conductive lines 112-1˜112-N that have short-circuited obtain voltage through the first conductive line 110 and/or the third conductive line 114. As a result, the second transistors 132 connected to the one or more of the sub-conductive lines 112-1˜112-N that have short-circuited are turned on. Therefore, in the SEM image, the second contacts 142 of the second transistors 132 that are turned on no longer keep in the “dark” state, but are in the “bright” state due to having more electrons. For example, in the event of a short-circuit between the sub-conductive line 112-2 and the first conductive line 110 and/or the third conductive line 114, the second transistors 132-3 and 132-4 connected to the sub-conductive line 112-2 are turned on. Therefore, the second contacts 142 of the second transistors 132-3 and 132-4 are in the “bright” state. According to the “bright” state of the second contacts 142 of the second transistors 132-3 and 132-4, it is determined that there is the defect between the sub-conductive line 112-2 of the second conductive line 112 and other conductive lines.

By dividing the second conductive line 112 into the plurality of sub-conductive lines 112-1˜112-N, the region where the defect is located can be more accurately determined. When the second contacts 142 of the second transistors 132 connected to a sub-conductive line become bright, it means that there is a defect (e.g., short-circuit) between this sub-conductive line and other conductive lines. That is, the defect appears in the region where this sub-conductive line is located. In this way, it can be helpful for subsequent defect analysis.

In alternative embodiments, the first conductive line 110 and the third conductive line 114 can be divided into a plurality of sub-conductive lines and maintain the integrity of the second conductive line 112. Moreover, use the first electron beam to irradiate the second conductive line contact 152 to make the second transistors 132 be turned on, while the first transistors 130 and the third transistors 134 are not turned on. Therefore, in the normal state, in the SEM image, the second contacts 142 are in the “bright” state, while the first contacts 140 and the third contacts 144 keep in the “dark” state. On the other hand, in the abnormal state, in the SEM image, the first contacts 140 correlated with the sub-conductive line of the first conductive line 110 in which a short-circuit occurs and the third contacts 144 correlated with the sub-conductive line of the third conductive line 114 in which a short-circuit occurs will appear the “bright” state. In this way, it can also determine whether there is a defect (e.g., short-circuit) between the conductive lines by the change of the “bright” and “dark” states of the contacts (e.g., the first contacts 140 and/or the third contacts 144). Furthermore, the region where the defect exists can be determined by the plurality of sub-conductive lines of the first conductive line 110 and the third conductive line 114.

For the purpose of simplicity and clarity, FIGS. 1A to 4B only illustrate the necessary features. However, those skilled in the art should understand that they may readily add other features to complete the semiconductor device, and may also add other elements on the semiconductor structures 100 and 200 to form other semiconductor applications.

Refer to FIG. 5, the inspection system 500 may include the function of a scanning electron microscope. The inspection system 500 includes an electron beam emitting system, and the electron beam emitting system includes an electron source 510, a first aperture diaphragm 520, a condenser lens 530, a second aperture diaphragm 525, a deflector 540 and a detector 570. The inspection system 500 further includes a stage 550 and a processing device 580. The stage 550 may be used to carry a sample 560, such as the semiconductor structures 100 and 200.

The electron source 510 may be used to emit electron beams toward the sample 560, such as the first electron beam for pre-charging the conductive line contacts and the second electron beam for scanning the sample to generate the SEM image. The first aperture diaphragm 520 and the second aperture diaphragm 525 may be used to control the convergence angle of the electron beams. The condenser lens 530 and an objective lens (not shown) that is closer to the sample 560 may be used to focus the electron beams. The deflector 540, such as a coil, may be used to control the paths of the electron beams.

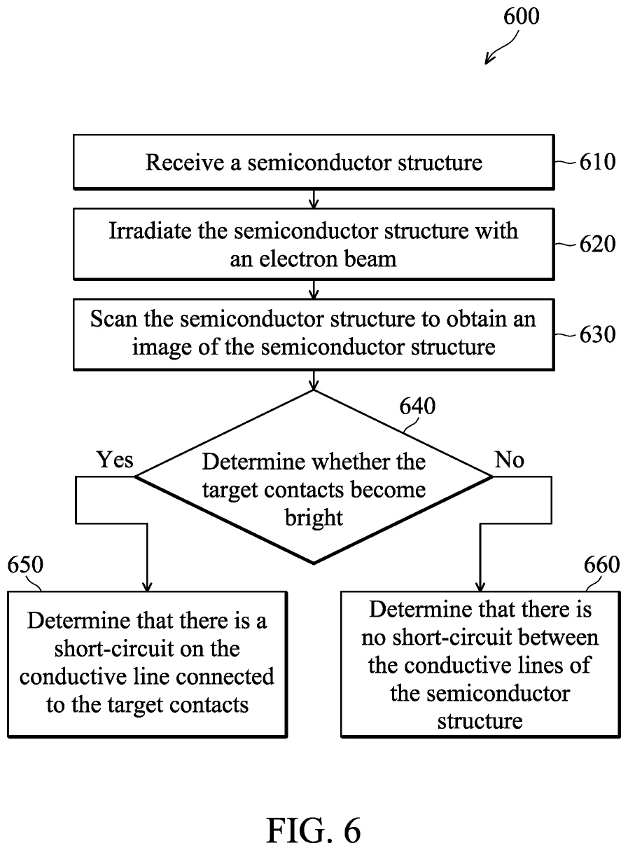

The detector 570 may receive secondary electrons produced by the sample 560 due to the second electron beam of the electron source 510, and generate the SEM image of the sample 560. For example, the SEM image is generated by the processing device 580. The processing device 580 may be used to perform the inspection method provided by the present disclosure, such as the method 600 described below with reference to FIG. 6. For example, the method 600 may be implemented as a computer program product and stored in a storage device (not shown) of the inspection system 500. The computer program product stored in the storage device can be loaded and executed by the processing device 580 to perform the method 600 in the inspection system 500.

FIG. 6 illustrates a flow chart of the method 600 for inspecting a semiconductor structure (e.g., the semiconductor structures 100 and 200), in accordance with some embodiments of the present disclosure. It is noted that, additional operations may be provided before, during or after the method 600, and some operations described can be moved, replaced, or eliminated for additional embodiments of the method 600. FIG. 6 will be described below while referring to FIGS. 1A to 5.

In operation 610, a semiconductor structure is first received. The semiconductor structure at least includes a first conductive line, a second conductive line, first transistors connected to the first conductive line and having first contacts, second transistors connected to the second conductive line and having second contacts, and a first conductive line contact connected to the first conductive line.

In operation 620, irradiating at least one conductive line contact of the semiconductor structure with an electron beam to pre-charge a conductive line connected to the at least one conductive line contact and turn on transistors connected to the conductive line. For example, the electron source 510 may be used to irradiate the conductive line contact of at least one conductive line of the semiconductor structure 100 and/or 200 with the first electron beam to pre-charge the at least one conductive line, and turn on transistors connected to the at least one conductive line.

In operation 630, scanning the semiconductor structure with an electron beam to obtain an image, such as a SEM image, of the semiconductor structure. For example, the electron source 510 may be used to scan the semiconductor structure 100 and/or 200 with the second electron beam to produce secondary electrons. Then, the detector 570 may be used to receive the secondary electrons that come from the semiconductor structure 100 and/or 200 to generate a SEM image of the semiconductor structure 100 and/or 200.

In operation 640, determining whether target contacts become bright according to the image obtained in operation 630. In response to the target contacts becoming bright, the operation 650 of the method 600 is proceeded. In response to the target contacts not becoming bright, the operation 660 of the method 600 is proceeded. For example, the processing device 580 may be used to process the SEM image to determine whether the target contacts become bright.

As described above, whether the transistors are turned on or not can be determined by the “bright” and “dark” states of the contacts in the SEM image. The transistors connected to the conductive line that is not pre-charged may be set as target transistors, so that the target transistors will not be turned on due to the pre-charging. At the same time, the contacts of the target transistors may be set as target contacts, and the conductive line that is not pre-charged connected to the target transistors may be set as a target conductive line. As a result, in the normal state, the target contacts of the target transistors should appear the “dark” state in the SEM image. If the target contacts become bright in the SEM image (i.e., they appear the “bright” state meaning they are turned on), it means that the target conductive line of the target transistors obtains voltage from other place due to the existence of the defect and thus turns on the target transistors. In this way, it can be determined that the target conductive line of the target transistors has a defect (e.g., there is a short-circuit between the target conductive line and other conductive lines that have been pre-charged).

After determining that the target contacts become bright, the operation 650 of the method 600 is proceeded. In operation 650, it is determined that there is a short-circuit on the conductive line connected to the target contacts. As described above, when the target contacts appear the “bright” state in the SEM image, it means that the target conductive line has a defect. Therefore, in response to the target contacts becoming bright, there is a defect (e.g., a short-circuit) between the conductive lines of the semiconductor structure is determined in operation 650 of the method 600.

After determining that the target contacts do not become bright, the operation 660 of the method 600 is proceeded. In operation 660, it is determined that there is no short-circuit between the conductive lines of the semiconductor structure. As described above, in the normal state, the target contacts of the target transistors should appear the “dark” state in the SEM image. Therefore, in response to the target contacts not becoming bright, in operation 660 of the method 600, it determines that the semiconductor structure is in the normal state. That is, there is no short-circuit between the conductive lines of the semiconductor structure.

In further embodiments, the target conductive line connected to the target transistors may be further divided into a plurality of sub-conductive lines in the method 600. As described above, in this way, the region where the defect is located can be determined more accurately.

After the operation 650, further operations may be performed, such as performing defect analysis (e.g., physical failure analysis, PFA) on the semiconductor structure, so as to facilitate a subsequent improvement in the process. As described above, by dividing the target conductive line of the target transistors into a plurality of sub-conductive lines, the region where the defect is located can be determined more accurately, thereby improving the defect analysis. For example, after the region where the defect is located is determined according to the sub-conductive lines, the defect analysis may be performed on this region.

The present disclosure provides an inspection method and an inspection system utilizing the inspection method. In the inspection method, the change of “bright” and “dark” states of contacts of transistors in the SEM image is used to determine whether there is a defect causing a short-circuit between a conductive line and other conductive lines, wherein the conductive line is connected to the gates of the transistors, or it acts as the gates of the transistors. As described above, in the SEM image, a defect (e.g., a short-circuit) between the conductive lines will cause the contacts that should appear the “dark” stack to instead appear the “bright” state. Therefore, it is possible to determine whether there is a defect between the conductive lines according to the “bright” and “dark” states of the contacts. The inspection method provided by the present disclosure can provide the many benefits mentioned above. Among these benefits, it may be easier to detect the existence of defects. Inspection can be performed while the conductive lines are covered with other components. The time and cost of redesigning the process as well as interrupting the process and frequently entering/exiting the process chamber can be avoided. The inspection result of the test key can be more highly consistent with the real chip, and thus the inspection accuracy can be improved. The region where the defect is located can be determined more accurately.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An inspection method for inspecting a semiconductor structure, the semiconductor structure comprises:
a first conductive line and a second conductive line, extending in a first direction and spaced apart from each other in a second direction;
first transistors, connected to the first conductive line, wherein each of the first transistors includes a first contact;
second transistors, connected to the second conductive line, wherein each of the second transistors includes a second contact; and
a first conductive line contact, connected to the first conductive line; and
the inspection method comprises:
a pre-charge operation, irradiating the first conductive line contact with an electron beam;
an imaging operation, obtaining an image of the semiconductor structure; and
a determination operation, determining whether the second contact of any one of the second transistors becomes bright in the image, and in response to the second contact of the any one of the second transistors becoming bright, determining that there is a defect between the first conductive line and the second conductive line.

2. The inspection method as claimed in claim 1, wherein the first transistors and the second transistors are alternately disposed along the first direction.

3. The inspection method as claimed in claim 1, wherein the second conductive line comprises sub-conductive lines, the sub-conductive lines at least include a first sub-conductive line and a second sub-conductive line, and the determination operation further comprises:
in response to the second contact of the second transistors connected to the first sub-conductive line becoming bright in the image, determining that there is a defect between the first sub-conductive line and the first conductive line.

4. The inspection method as claimed in claim 3, further comprising: performing a physical failure analysis on a region where the first sub-conductive line is located in the semiconductor structure.

5. The inspection method as claimed in claim 1, wherein the first conductive line acts as gates of the first transistors, and the second conductive line acts as gates of the second transistors.

6. The inspection method as claimed in claim 5, wherein:
each of the first transistors further includes a first isolation structure, wherein the first isolation structure is disposed over the first conductive line; and
each of the second transistors further includes a second isolation structure, wherein the second isolation structure is disposed over the second conductive line.

7. The inspection method as claimed in claim 6, wherein the semiconductor structure further comprises a substrate, wherein the first isolation structure, the first conductive line, the second isolation structure, and the second conductive line are disposed in the substrate, and wherein the first contact and the second contact are disposed in an interlayer dielectric layer that is over the substrate.

8. The inspection method as claimed in claim 1, wherein:
each of the first transistors further includes a third contact, wherein the first contact and the third contact are disposed on opposite sides of the first conductive line in the second direction; and
each of the second transistors further includes a fourth contact, wherein the second contact and the fourth contact are disposed on opposite sides of the second conductive line in the second direction.

9. A semiconductor structure, comprising:
a first conductive line and a second conductive line, extending in a first direction and spaced apart from each other in a second direction;
first transistors, connected to the first conductive line, wherein each of the first transistors includes a first contact;
second transistors, connected to the second conductive line, wherein each of the second transistors includes a second contact; and
a first conductive line contact, connected to the first conductive line.

10. The semiconductor structure as claimed in claim 9, wherein the first transistors and the second transistors are alternately disposed in the first direction.

11. The semiconductor structure as claimed in claim 9, wherein the second conductive line comprises sub-conductive lines, the sub-conductive lines at least include a first sub-conductive line and a second sub-conductive line.

12. The semiconductor structure as claimed in claim 9, further comprising a second conductive line contact connected to the second conductive line, wherein the first conductive line contact is disposed on a first side of the semiconductor structure and the second conductive line contact is disposed on a second side of the semiconductor structure, and wherein the second side is opposite to the first side in the first direction.

13. The semiconductor structure as claimed in claim 9, wherein the first conductive line acts as gates of the first transistors, and the second conductive line acts as gates of the second transistors.

14. The semiconductor structure as claimed in claim 13, wherein:
each of the first transistors further includes a first isolation structure, wherein the first isolation structure is disposed over the first conductive line; and
each of the second transistors further includes a second isolation structure, wherein the second isolation structure is disposed over the second conductive line.

15. The semiconductor structure as claimed in claim 14, further comprising a substrate, wherein the first isolation structure, the first conductive line, the second isolation structure, and the second conductive line are disposed in the substrate, and wherein the first contact and the second contact are disposed in an interlayer dielectric layer that is over the substrate.

16. The semiconductor structure as claimed in claim 9, wherein:
each of the first transistors further includes a third contact, wherein the first contact and the third contact are disposed on opposite sides of the first conductive line in the second direction; and
each of the second transistors further includes a fourth contact, wherein the second contact and the fourth contact are disposed on opposite sides of the second conductive line in the second direction.

17. An inspection system for inspecting the semiconductor structure as claimed in claim 9, the inspection system comprises:
an electron beam emitting system having an electron source and a detector;
a stage, configured to carry the semiconductor structure; and
a processing device, configured to perform following operations:
a pre-charge operation, emitting an electron beam toward the first conductive line contact of the semiconductor structure through the electron source;
an imaging operation, scanning the semiconductor structure and receiving secondary electrons that come from the semiconductor structure through the detector to generate an image of the semiconductor structure; and
a determination operation, determining a bright state and a dark state in the image to determine whether there is a defect between the first conductive line and the second conductive line of the semiconductor structure.

18. The inspection system as claimed in claim 17, wherein in response to the second contact of any one of the second transistors being in the bright state in the image, the determination operation determines that there is a defect between the first conductive line and the second conductive line.

19. The inspection system as claimed in claim 17, wherein the second conductive line comprises sub-conductive lines at least including a first sub-conductive line and a second sub-conductive line, and in response to the second contact of the second transistors connected to the first sub-conductive line being in the bright state in the image, the determination operation determines that there is a defect between the first sub-conductive line and the first conductive line.

20. The inspection system as claimed in claim 17, wherein in response to the second contact of each of the second transistors being in the dark state in the image, the determination operation determines that there is no defect between the first conductive line and the second conductive line.
